(19) United States
(12) Patent Application Publication
(10) Pub. No.: US 2008/0289953 A1
(43) Pub. Date: Nov. 27, 2008

(54) High rate sputtering apparatus and method

(75) Inventor: Dennis Hollars, San Jose, CA (US)

Correspondence Address: FOLEY AND LARDNER LLP;SUITE 500, 3000 K STREET NW, WASHINGTON, DC, 20007, US

(73) Assignee: Miasole

(21) Appl. No.: 12/153,615

(22) Filed: May 21, 2008

Related U.S. Application Data
(60) Provisional application No. 60/939,431, filed on May 22, 2007.

(51) Int. Cl. C23C 14/00; C23C 14/35

(52) U.S. Cl. 204/192.1; 204/298.09

(57) ABSTRACT

The invention provides a sputtering method that involves exposing a surface of a target support to a flow of a target material, such that the exposing results in condensing the target material on the surface of the target support in a first position and sputtering the condensed target material from the surface of the target support in a second position to a substrate, wherein the surface of the target support in the second position is not exposed to the flow of the evaporated target material during the sputtering. A sputtering target unit also provided. The sputtering method and the sputtering target unit allow performing a high rate sputtering of poor thermal conductors.

### CROSS-REFERENCE TO RELATED PATENT APPLICATIONS

The present application claims benefit of U.S. provisional application 60/939,431, filed May 22, 2007, which is incorporated herein by reference in its entirety.

### FIELD

The present invention relates generally to sputtering apparatuses and methods, and more specifically, to apparatuses capable of high rate sputtering of poor thermal conductors and related methods.

### BACKGROUND

Fabricating chalcogenides for cost effective thin-film solar cells can involve depositing chalcogenes, such as sulfur, selenium and tellurium. Chalcogenes are poor thermal conductors and, therefore, can be very difficult to sputter at high rates using conventional methods because sputtering targets made of poor thermal conductors tend to melt or otherwise fail under high sputtering power.

For example, in case of selenium, sputtering targets are available commercially. Selenium sputtering targets can be also fabricated in a lab fairly easily as selenium's melting point of 217° C. is relatively low. Unfortunately, due to selenium's low thermal conductivity, the sputtering rates from the commercial or in-house fabricated selenium targets must be kept very low. As the sputtering power increases, the selenium target heats up and melts. While such heating up and melting may be not catastrophic in a sputter up mode, it can present a serious control issue due to the developing thermal evaporation flux from the target as thermal evaporation rates of selenium become very high in vacuum even at temperatures near its melting point.

Due to the difficulties with chalcogene sputtering by conventional methods, chalcogenides are often fabricated via either traditional thermal evaporation or chemical vapor deposition using chalcogene containing gaseous compounds.

Evaporation of chalcogenes has problems of its own. For example, evaporation of selenium produces mostly chains or rings typically of 5 to 8 or more selenium atoms, while normal diatomic selenium species are present only in small amounts and monoatomic selenium may be not present at all in any detectable quantities. Such a distribution of selenium species means that the deposited selenium has a low chemical activity and thus is inefficient for forming selenides with other constituents. As a result, a large excess of selenium with respect to other constituents may be required to form a desired selenide. For example, for forming copper indium diselenide, an excess of selenium over copper and indium can be as high as 4 times. Not only is such approach wasteful, it also has low deposition rates and long deposition times due to a low reactivity of evaporated selenium and thus is not applied for high rate production.

Little has improved in sputtering low conductivity materials, such as selenium, using conventional methods. As discussed above, relatively thick selenium targets melt and/or crack when sputtered at high power. Although selenium sputtered from such relatively thick target is largely in atomic or negative ionic forms, which are far more active and desirable than the thermally evaporated forms of selenium, the net sputtering process slows down significantly to accommodate the target's frailty. Instead of relatively thick selenium targets, one can use thinner selenium targets. High sputtering power can be applied for such thinner targets before they are consumed. Still, such thinner targets are not satisfactory for high rate production. For example, even in the best case of crystallographic orientation, thin selenium target has to be only about 0.0025″ thick to have the same surface temperature for sputtering at 10 kW as a typically sized efficiently cooled 0.25″ thick copper target.

In sum, a need exists to develop methods and apparatuses which would allow depositing poor thermal conductors, such as chalcogenes, at high rates.

### SUMMARY

In one embodiment, the invention provides a sputtering target unit, comprising a chamber configured for containing a target material; a manifold having an inlet and an outlet, wherein the inlet of the manifold is in fluidic connection with the chamber; one or more heaters configured for evaporating the target material in the chamber and maintaining the target material in the evaporated form in the manifold; and a target support having a surface, wherein the unit is configured to switch between a first state, where the surface of the target support is in fluidic connection with the chamber via the manifold, and a second state, where the surface of the target support is not in fluidic connection with the chamber via the manifold.

In another embodiment, the invention provides a sputtering method comprising exposing a surface of a target support in a first position to a flow of a target material, wherein the exposing results in condensing the target material on the surface of the target support and sputtering the condensed target material from the surface of the target support in a second to a substrate, wherein the surface of the target support in the second state is not exposed to the flow of the target material.

In yet another embodiment, the invention provides a sputtering target unit, comprising a target support having a surface, a means for evaporating a target material; a means for directing the evaporated target material to the surface of the target support in a first position, and a means for sputtering the target material from the surface when the target support is in a second position such that the target material being sputtered from the surface is not exposed to a flow of the evaporated target material.

And in yet another embodiment, the invention provides a sputtering method comprising depositing a target material on a target support inside a vacuum enclosure of a sputtering apparatus, and sputtering the target material from the target support on a substrate inside the vacuum enclosure of the sputtering apparatus.

### DRAWINGS

FIG. 1 is a top cross-sectional view of a sputtering target unit according to one of the embodiments.

FIG. 2 is a side cross-sectional view of the unit of FIG. 1 along line A-A′. The view in FIG. 2 is perpendicular to that in FIG. 1.

### DETAILED DESCRIPTION

Unless otherwise specified, “a” or “an” refer to one or more.

The following patent documents, which are all incorporated herein by reference in their entirety, can useful for understanding the present invention:
1) U.S. Pat. No. 6,231,732;
2) U.S. Pat. No. 6,365,010;
3) U.S. Pat. No. 6,488,824;
4) U.S. Pat. No. 6,974,976;
5) US patent application No. 2004/0063320.

The present inventor developed a sputtering apparatus and a related sputtering method which allow for high rate sputtering of both good and poor thermal conductors. The invention can be used for sputtering a material that has a thermal conductivity at 300 Kelvin of less than 400 W/(m×K), such as less than 100 W/(m×K), for example, less than 10 W/(m×K), including 0.1 to 10 W/(m×K), such as 0.2 to 4 W/(m×K). In some embodiments, the apparatus can be used for sputtering a chalcogene, such as sulfur (300K thermal conductivity of about 0.205 W/(m×K)); selenium (300K thermal conductivity of about 0.519 W/(m×K)) or tellurium (300K thermal conductivity of about 1.97-3.38 W/(m×K)).

In general, the sputtering method includes depositing a target material on a target support located inside a vacuum enclosure of a sputtering apparatus (i.e., forming the target material on the target support in-situ rather than placing the pre-formed sputtering target into the vacuum enclosure of the sputtering apparatus). The target material may be deposited by evaporation or other suitable deposition methods. It should be noted that the step of depositing the target material involves intentionally depositing the target material on the target support from a separate source or reservoir of target material rather than the unintentional re-deposition of the sputtered off target material back onto the target support. The method also includes sputtering the target material from the target support on a substrate inside the vacuum enclosure of the sputtering apparatus to form a thin film on the substrate. In a preferred embodiment, the sputtering method involves first evaporating a target material, which can be a poor thermal conductor, and condensing the evaporated target material on a surface of a target support, which can be planar or curved, to form a sputtering target comprising the target material. The method also comprises sputtering the target material from the surface of the target support to a substrate.

In some embodiments, evaporation of the target material can be performed within a vacuum enclosure of a sputtering apparatus. Yet in some other embodiments, the target material can evaporated outside a vacuum enclosure of a sputtering apparatus and fed through a manifold inside the vacuum enclosure.

Evaporation of the target material can involve exposure to low pressure (vacuum) inside the vacuum enclosure of the sputtering apparatus. Evaporation of the target material can be also facilitated by heating the target material. A temperature to which the target material is heated for evaporation, can be lower than a boiling point of the target material under atmospheric pressure.

Preferably, when the target material is sputtered from the surface of the target support, the surface of the target support is not exposed to the evaporated target material. This can be accomplished, for example, by using a target support that moves with respect to the source of the evaporated target material. For example, such a movable target support can move between at least two positions: a first position, where the surface of the target support faces a flow of the evaporated target material and a second position, where the surface of the target support faces away from the flow of the evaporated target material. The movement of the target support can include rotation and/or translation. For example, in some cases, the movable target support can be a rotating target support, i.e. a cylindrical target support that is capable of rotating around a stationary axis.

Exposure of the surface of the target support to the flow of the evaporated target material during the sputtering can be also prevented by moving a source of the evaporated target material away from the surface of the target support or by interrupting the flow of the evaporated target material to the surface of the target support by using, for example, a valve.

A thickness of the target material condensed on the surface of the target support can be controlled by, for example, regulating the flow of the evaporated target material using a valve or another flow regulator. For example, the thickness of the condensed target material can be controlled to be no greater than an effective sputtering thickness for the target material, which is a maximum thickness for which the target material does not melt and/or crack under a particular sputtering power. The effective sputtering thickness can depend on physical properties of a particular target material, such as a thermal conductivity, a melting point and a coefficient of thermal expansion, and on the desired sputtering power.

Due to the thickness control, sputtering can be performed at high sputtering power, which can be at least 3 kW, or at least 5 kW, or at least 8 kW or at least 10 kW, such as 3-12 kW.

The method can provide an ability to replenish a thin target which does not melt and/or crack, for deposition of a desired amount of the target material. Such replenishing can be performed either continuously or intermittently during sputtering and/or between sputtering runs. For example, a first area or portion of the surface of the target support can be exposed to the flow of the evaporated target material, while sputtering of the condensed target material can be performed from a second area or portion of the surface of the target support. The second area or portion is not exposed to the flow of the evaporated target material at the same time as the first area or portion. The first area and the second area can be then exchanged with respect to the exposure to the flow of the evaporated target material, i.e. sputtering can continue from the first area, which is now not exposed to the flow of the evaporated target material, while the condensed target material can be replenished on the second area.

The method can also include monitoring sputtering emission from the surface of the target support during the sputtering. Such monitoring can be used for determining when the condensed target material needs to be replenished on the target support. Monitoring sputtering emission can be performed optically by monitoring one or more emission lines associated with the target material and/or one or more emission lines associated with a material of the surface of the target support. Decrease in the emission associated with the target material and/or appearance of the emission associated with the material of the surface of the target support can indicate that the target material on the surface of the target support needs to be replenished.

The method can be used for any type of sputtering including DC, AC and RF sputtering. Preferably, the method is used for magnetron sputtering, including DC, AC and RF sputtering.

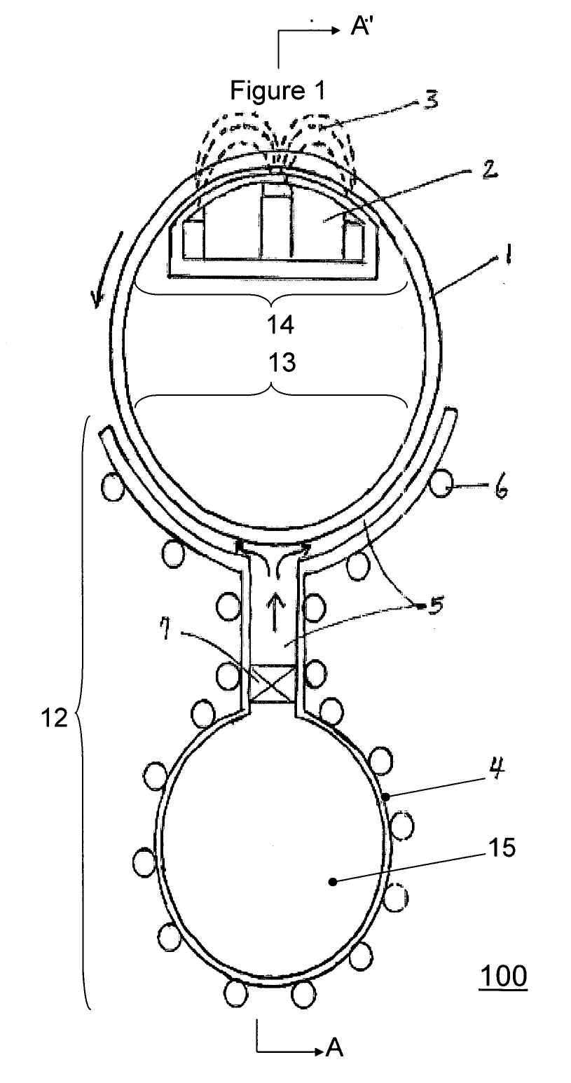

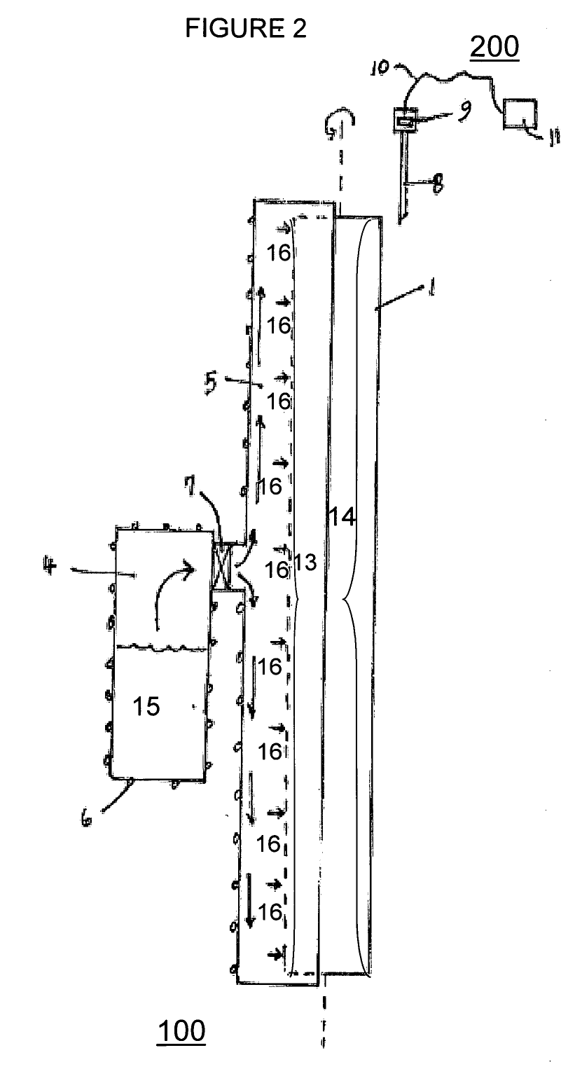

FIGS. 1 and 2 illustrate one non-limiting embodiment of a sputtering target unit, which can be used for performing the described above process.

A sputtering target unit 100 in FIGS. 1 and 2 includes a chamber or vessel 4 that can contain a target material 15 to be sputtered. The chamber or vessel 4 is in fluidic connection with an inlet of a manifold or distributor 5. An outlet of the manifold or distributor 5 is in fluidic connection with a subarea of an outer surface of a target support 1. Heaters 6 are positioned in thermal contact with the chamber or vessel 4 and the manifold or distributor 5. The heaters 6 can be used for evaporating the target material 15 contained in the chamber or vessel 4 and maintaining the target material in a vapor state when it passes through the manifold or distributor 5. The manifold or distributor 5 contains a valve or a flow regulator 7 that controls a flow of the evaporated target material through the manifold or distributor 5 to the target support 1. The chamber or vessel 4 and the manifold or distributor 5 form a source of the evaporated target material.

The target support 1 is positioned with respect to the manifold or distributor 5 so that at any given time a first portion 13 of its outer surface is in fluidic connection with and faces the manifold and thus can be exposed to the flow of the evaporated target material 15, while a second portion 14 of its outer surface is not in fluidic connection with and faces away from the manifold or distributor 5 and thus is not exposed to the flow of the evaporated target material 15. As illustrated in FIG. 1, the target support 1 can be a cylindrical tube that can rotate around the axis perpendicular to the plane of FIG. 1 so that different portions of its outer surface can be brought in fluidic connection with the manifold or distributor 5 by rotation around its axis to face the manifold or distributor 5. The manifold or distributor 5 has outlets 16 providing an access for the evaporated target material 15 to the surface of the target support 1 as shown in FIG. 2. Preferably, the manifold or distributor 5 is such that a path of the evaporated target material through the manifold or distributor 5 for each of the outlets 16 is the same. Such a feature can provide a uniform distribution of the target material over the length of the target support 1.

After passing through the manifold or distributor 5 the evaporated target material can be condensed on the portion of the outer surface of the target support 1 that faces the manifold or distributor 5, such as portion 13 in FIG. 1. To facilitate the condensation of the evaporated target material and thereby prevent condensation of the evaporated target material on other parts of a sputtering apparatus, the target support 1 can contain a cooling element for cooling down its outer surface. Such a cooling element can include a circulating cooling liquid, such as water, in thermal contact with the outer surface of the target support.

The target material condensed on the outer surface of the target support 1 can be used as a sputtering target. To sputter the condensed target material, the target support 1 can be rotated around an axis perpendicular to the plane of FIG. 1 so that the portion 14 of its outer surface with the condensed target material is in a “sputtering” position, which faces away from the manifold 5 and, thus, is not exposed to the flow of the evaporated target material 15.

The sputtering target unit 100 can be used for any type of sputtering including DC, AC and RF sputtering. Preferably, the sputtering target unit is used for magnetron sputtering including DC, AC and RF magnetron sputtering. For magnetron sputtering, the sputtering target unit can include a magnet assembly 2. The magnet assembly 2 can be positioned with respect to the target support 1 so that the portion 14 of the outer surface of the target support 1 facing away from the manifold or distributor 5 gets exposed to the magnetic field 3 of the assembly 2.

The sputtering target unit 100 can be part of a sputtering apparatus of any type. In some cases, the sputtering target unit 100 can comprise the sole sputtering source of the sputtering apparatus. Yet in some cases, the sputtering target unit 100 can be one of multiple sputtering sources of the sputtering apparatus. For example, in some cases, the sputtering target unit 100 can be used in combination with one or more prior art rotary magnetrons of the dual or triple magnetron sputtering systems, shown in U.S. Pat. No. 6,488,824 (FIGS. 2C, 3A-C, 14-16), or in U.S. Pat. No. 6,974,976 (FIG. 9).

In some embodiments, the entire sputtering target unit 100 can be housed inside a vacuum enclosure of the sputtering apparatus which also contains the substrate support on which the substrate to be coated is to be provided. Yet in some other embodiments, the chamber or vessel 4 can be placed outside the vacuum enclosure of the sputtering apparatus and the manifold or distributor 5 can be used to feed the evaporated material inside the vacuum enclosure to the target support 1.

The chamber or vessel 4 and the manifold or distributor 5 can be made of any appropriate materials as long as they are thermally conductive, vacuum proof and do not react with the target material.

The target support 1 can include any appropriate material compatible with high power sputtering. Preferably, the outer surface of the target support is made of a material that does not interfere significantly with desired properties of the sputtered target material when inadvertently sputtered due to a low level of the target material on the surface of the target support. For example, when the target material is selenium used for producing copper indium diselenide photovoltaic layer for a thin film photovoltaic cell, such a non-interfering material can be aluminum as incorporation of aluminum does not significantly raise a band gap of the copper indium diselenide. In some embodiments, the non-interfering material can be introduced as a layer on the outer surface of the target support, while the rest of the target support has a different material composition. Yet in some other embodiments, the non-interfering material can be the material of which the whole target support is made of.

When the sputtering target unit 100 is a part of a sputtering apparatus, monitoring of sputtering emission from the target support I can be performed using an emission control unit 200. As illustrated in FIG. 2, the emission control unit 200 can include a flux shield tube 8, an optically clear vacuum window 9, a fiber optic cable 10 and a spectrometer 11. The flux shield tube 8 and the optically clear vacuum window 9 can be placed using an optical feed through in the vacuum enclosure of the sputtering apparatus. Preferably, the flux shield tube 8 and the optically clear vacuum window 9 are positioned in the sputtering apparatus with respect to the sputtering target unit I 00 so that the emission control unit collects emission light from an area of intense sputtering emission from the surface of the target support 1. For example, for magnetron sputtering, such as area is a region of magnetic field 3 produced by the magnetic assembly 2 illustrated in FIG. 1. Accordingly, as depicted in FIG. 2, the flux shield tube 8 and the optically clear vacuum window 9 are positioned above the region of magnetic field 3.

In some embodiments, the spectrometer 11 can be small in size to fit inside the sputtering apparatus. In some other embodiments, the spectrometer 11 can be an external spectrometer. A light can be fed to the external spectrometer using the fiber optic cable 10. As an alternative to the spectrometer 11, the emission control monitoring unit can contain an interference filter with a narrow band pass for a particular emission line of interest. Such emission line of interest can be a particular emission line of interest of the target material or a particular emission line of interest of the material of the surface of the target support. Although the interference filter provides a more economical implementation of the emission control unit, the spectrometer in the emission control unit allows for a greater versatility. The emission control monitoring unit 200 can be functionally connected with the valve 7, a motor or another mechanism responsible for the rotation of the target unit 1 and/or heaters 6 so that when the thickness of the target material on the target support is detected to be low by, for example, observing or detecting emission associated with the material of the surface of the target support, the target material on the target support can be replenished. The valve 7, motor and/or heaters 6 may be controlled by an operator via a control interface or automatically by a computer or other logic device or circuit.

The sputtering target unit 100 can be used for a variety of applications. For example, the sputtering target unit containing a chalcogene as a target material can be used in a sputtering apparatus that also contains an additional sputtering source containing a metal or metal alloy sputtering target to produce metal chalcogenide photovoltaic layer for a thin film solar cells. For example, when the chalcogene is selenium, the metal or metal alloy sputtering target can be a copper indium alloy target, copper indium gallium alloy target or copper indium aluminum alloy target and the resulting metal chalcogenide can be copper indium diselenide (CIS), copper indium gallium diselenide (CIGS) or copper indium aluminum diselenide.

Although the foregoing refers to particular preferred embodiments, it will be understood that the present invention is not so limited. It will occur to those of ordinary skill in the art that various modifications may be made to the disclosed embodiments and that such modifications are intended to be within the scope of the present invention.

All of the publications, patent applications and patents cited in this specification are incorporated herein by reference in their entirety.

What is claimed is:

1. A sputtering target unit, comprising:
(A) a chamber configured for containing a target material;
(B) a manifold having an inlet and an outlet, wherein the inlet of the manifold is in fluidic connection with the chamber;
(C) one or more heaters configured for evaporating the target material in the chamber and maintaining the target material in the evaporated form in the manifold; and
(D) a target support having a surface, wherein the unit is configured to switch between a first state, where the surface of the target support is in fluidic connection with the chamber via the manifold, and a second state, where the surface of the target support is not in fluidic connection with the chamber via the manifold.

2. The sputtering target unit of claim 1, wherein the target material having a thermal conductivity lower than 10 W/(m×K) is contained in the chamber.

3. The sputtering target unit of claim 2, wherein the target material is a chalcogene.

4. The sputtering target unit of claim 3, wherein the chalcogene is sulfur, selenium or tellurium.

5. The sputtering target unit of claim 1, wherein:
the target support is a rotating target support; and
a rotation of the rotating target switches a position of the surface of the target relative to the outlet of the manifold.

6. The sputtering target unit of claim 5, wherein the target support is a cylindrical target support.

7. The sputtering target unit of claim 1, further comprising a cooling element configured to cool down the surface of the target support.

8. The sputtering target unit of claim 7, wherein the cooling element is a cooling system configured for circulating a cooling fluid.

9. The sputtering target unit of claim 1, further comprising a magnet positioned to expose the surface of the target support to a magnetic field when the unit is in the second state.

10. The sputtering target unit of claim 1, wherein the manifold comprises a valve or a regulator configured to regulate a flow of the evaporated target material through the manifold.

11. A sputtering apparatus comprising the sputtering target unit of claim 1, wherein the sputtering target unit in the second state is adapted for sputtering the target material from the surface of the target support on a substrate.

12. The sputtering apparatus of claim 11, further comprising an additional sputtering source configured for sputtering an additional material on the substrate.

13. The sputtering apparatus of claim 12, wherein the additional sputtering source is a rotary magnetron sputtering source.

14. The sputtering apparatus of claim 11, wherein the sputtering target unit further comprises an emission control subunit configured to monitor sputtering emission from the surface of the target support, when the sputtering target unit is in the second state.

15. The sputtering apparatus of claim 14, wherein the emission control subunit comprises a flux shield tube, an optically clear vacuum window, a fiber optic cable and a spectral analyzer.

16. The sputtering apparatus of claim 15, wherein the spectral analyzer is a spectral line filter configured to detect one or more emission lines of a material of the surface of the target support.

17. The sputtering apparatus of claim 15, wherein the spectral analyzer is a spectrometer.

18. A sputtering method, comprising:
exposing a surface of a target support in a first position to a flow of a target material, wherein the exposing results in condensing the target material on the surface of the target support; and
sputtering the condensed target material from the surface of the target support in a second position to a substrate, wherein the target material being sputtered from the surface of the target support is not exposed to the flow of the evaporated target material.

19. The method of claim 18, wherein the target material has a thermal conductivity no greater than 10 W/(m×K).

20. The method of claim 19, wherein the target material is a chalcogene.

21. The method of claim 20, wherein the chalcogene is sulfur, selenium or tellurium.

22. The method of claim 18, further comprising evaporating the target material located in a chamber to generate the flow of the target material.

23. The method of claim 22, further comprising moving the surface of the target support from the first position, where the surface of the target support is exposed to the flow of the evaporated target material, to the second position, where the surface of the target support is not exposed to the flow of the evaporated target material.

24. The method of claim 23, wherein the step of moving comprises rotating the target support around an axis.

25. The method of claim 18, further comprising controlling a thickness of the condensed target material on the surface.

26. The method of claim 25, wherein the controlling comprises regulating the flow of the evaporated target material.

27. The method of claim 18, wherein the thickness of the condensed target material on the surface is an effective sputtering thickness of the target material.

28. The method of claim 18, wherein the sputtering is magnetron sputtering with a sputtering power of at least 3 kW.

29. The method of claim 18, further comprising sputtering an additional material on the substrate from an additional sputtering source.

30. The method of claim 29, wherein the additional sputtering source is a magnetron sputtering source.

31. The method of claim 18, further comprising monitoring a sputtering emission from the target support during the sputtering.

32. The method of claim 31, wherein the monitoring is performed optically.

33. A sputtering target unit, comprising:
a target support having a surface;
a means for evaporating a target material;
a means for directing the evaporated target material to the surface of the target support in a first position; and
a means for sputtering the target material from the surface when the target support is in a second position such that the target material being sputtered from the surface is not exposed to a flow of the evaporated target material.

34. A sputtering method, comprising:
depositing a target material on a target support inside a vacuum enclosure of a sputtering apparatus; and
sputtering the target material from the target support on a substrate inside the vacuum enclosure of the sputtering apparatus.
